(19) United States
(12) Patent Application Publication
(10) Pub. No.: US 2009/0000738 A1
(43) Pub. Date: Jan. 1, 2009

(54) ARRAYS OF INDUCTIVE ELEMENTS FOR MINIMIZING RADIAL NON-UNIFORMITY IN PLASMA

(76) Inventor: Neil Benjamin, Austin, TX (US)

Correspondence Address: IPSG, P.C., P.O. BOX 700640, SAN JOSE, CA, 95170, US

(21) Appl. No.: 12/145,393

(22) Filed: Jun. 24, 2008

Related U.S. Application Data
(60) Provisional application No. 60/947,380, filed on Jun. 29, 2007.

(51) Int. Cl. C23C 16/52

(52) U.S. Cl. 156/345.28

(57) ABSTRACT

An arrangement for enabling local control of power delivery within a plasma processing system having a plasma processing chamber during processing of a substrate is provided. The arrangement includes a dielectric window and an inductive arrangement. The inductive arrangement is disposed above the dielectric window to enable power to couple with a plasma in the plasma processing system. The inductive arrangement includes a set of inductive elements, which provides the local control of power delivery to create a substantially uniform plasma in the plasma processing chamber.

### PRIORITY CLAIM

This application is related to and claims priority under 35 U.S.C. §119(e) to a commonly assigned provisional patent application entitled “Arrays of Inductive Elements For Minimizing Radial Non-Uniformity in Plasma,” by Neil Benjamin, Attorney Docket Number P1541P/LMRX-P129P1, Application Ser. No. 60/947,380 filed on Jun. 29, 2007, incorporated by reference herein.

### BACKGROUND OF THE INVENTION

Advances in plasma processing have facilitated growth in the semiconductor industry. The demands for semiconductor devices, in recent years, have forced many manufacturers to become more competitive. One wax of increasing profitability is to maximize the real estate of a substrate. As a result, many manufacturers are processing to the edge of the substrate.

Unfortunately, substrate processing in a relatively large processing chamber, such as one that is capable of processing a substrate the size of 300 mm and/or larger, may present many challenges. One particular challenge is achieving a uniform result on the substrate to ensure the creation of defect-free semiconductor devices across the substrate.

In a typical processing environment, radio frequency (RF) energy may be fed into the processing chamber via electrode or antenna. Inside the processing chamber, the RF energy may interact with gas to produce plasma, which may interact with a substrate on an electrostatic chuck to create integrated circuits (ICs). In an ideal environment, the potential across the plasma and the substrate are uniform thereby creating a uniform result on the substrate. Realistically, the plasma created by the interaction between the RF energy and the gas is not uniform across the substrate due to the inherent nature of the processing chamber. In an example, the radial flow of gas may cause uneven distribution of gas throughout the processing chamber. In addition, non-uniformity may also be due to the topology of the substrates. In an example, most substrates and processes tend to have an edge effect during processing, which also contributes to non-uniformity.

In an attempt to control the uniformity of the plasma, IC fabricators have attempted to manage the different parameters (e.g., gas flow, gas exhaust, RF energy distribution, etc.) that may affect the condition of the processing chamber. In an example, the mass of the input gas flow may be controlled to ensure a more even distribution of gas. However, manipulating the different parameters in order to produce more uniform plasma is a tedious and time-consuming process that may require considerable optimization. Furthermore, uniform plasma usually does not translate into uniform etching on a substrate since other factors in the chamber or on the incoming substrate may affect uniformity. As a result, the task of managing the processing chamber environment in order to create plasma that may interact with the substrate to create uniform etching is a highly complex task that may be improved by local control.

Both segmented capacitive electrodes and dual coil inductive arrangement have been used to address uniformity control but only in a relatively coarse grain manner.

### BRIEF SUMMARY OF THE INVENTION

The invention relates, in an embodiment, to an arrangement for enabling local control of power delivery within a plasma processing system having a plasma processing chamber during processing of a substrate. The arrangement includes a dielectric window. The arrangement also includes an inductive arrangement. The inductive arrangement is disposed above the dielectric window to enable power to couple with a plasma in the plasma processing system. The inductive arrangement includes a set of inductive elements, which provides the local control of power delivery to create a substantially uniform plasma in the plasma processing chamber.

The above summary relates to only one of the many embodiments of the invention disclosed herein and is not intended to limit the scope of the invention, which is set forth in the claims herein. These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows, in an embodiment of the invention, an inductive arrangement for introducing RF energy into a plasma processing system.

FIG. 2-4 show, in embodiments of the invention, examples of different shapes for an inductive element.

FIG. 5-10 shows, in embodiments of the invention, examples of how the inductive elements may be arranged to provide uniform processing.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described hereinbelow, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

In one aspect of the invention, the inventor herein realized that local controls are needed in order to achieve more uniform processing. For instance, extremely high frequency (e.g., via 300 megahertz to 500 megahertz) capacitive arrays have been shown to produce inductive coupling due to the skin effect. However, the engineering of such a system may be unduly complex and expensive. Accordingly, it is desirable to implement a lower frequency (e.g., less than 300 megahertz) solution using conventional inductive and capacitive antenna coupling. This local control can be accomplished using an array of inductive and/or capacitive antenna elements.

In accordance with embodiments of the invention, innovative arrangements are provided in order to provide local control during substrate processing. In embodiments of the invention, the arrangement may include arrays of inductive elements arranged in a particular manner to provide local control. Also, in embodiments of the invention, the inductive elements may be of different shapes.

In an embodiment of the invention, inductive RF antennas may be placed above a dielectric window of a processing system in an array of inductive elements. Each inductive element may be arranged in such a manner that minimizes cross coupling and provides local control.

In an embodiment of the invention, the inductive arrangement may be a segmented loop arrangement. In an example, the segmented loop arrangement may include an array of straps connected to one another. In another example, the segmented loop arrangement may include an array of serpentine shapes. Each segment (e.g., inductive element) of the segmented loop arrangement may include a positive and a negative terminal. In an embodiment, current may flow from the positive to negative terminal. In an embodiment, a reverse mirror current may flow underneath the dielectric window. In an embodiment, the distance between the reverse mirror current and the segmented loop arrangement may be equal to or greater than the thickness of the dielectric window plus the thickness of a sheath and the thickness of the skin depth region, which is part of the plasma region.

In an embodiment of the invention, the inductive arrangement may be a ladder network arrangement. The ladder network arrangement may be a Cartesian arrangement in which a pair of inductive elements is separated from one another by equal to or greater than the thickness of the dielectric window plus the thickness of a sheath and the thickness of the skin depth region. The ladder network arrangement may include straps and/or serpentine shapes.

In an embodiment of the invention, the inductive arrangement may be a loop array arrangement. The loop array arrangement is an example of a simple Cartesian arrangement. In an embodiment, the loop array arrangement may be a rounded loop and/or a square loop. In an embodiment, each inductive element may be arranged in such a manner that allows the current for each inductive element to flow in the same direction. To minimize cross coupling and to prevent a global current effect, the inductive elements may be placed further apart. In an embodiment, the distance may be equal to or greater than the thickness of the dielectric window plus the thickness of a sheath and the thickness of the skin depth region.

In yet another embodiment of the invention, the inductive elements of the loop array arrangement may be arranged in a manner that enables the current of adjacent inductive elements to flow in opposite direction. To prevent the current from each inductive element to interfere with one another, the distance between each inductive element may be equal to or greater than the thickness of the dielectric window plus the thickness of a sheath and the thickness of the skin depth region.

In an embodiment of the invention, the inductive arrangement may be a face-centered arrangement, which may be a Cartesian arrangement Keith an offset center in the middle. Similar to the loop array arrangement, the shape of each inductive element may be a rounded loop and/or a square loop. Also, each adjacent inductive element may either be placed in a manner that enables the current of each inductive element to flow in the same direction or to flow in opposite direction. Similar to the loop array arrangement, the distance between the inductive arrangements may determine the amount of local control each inductive element have over substrate processing.

The features and advantages of the present invention may be better understood with reference to the figures and discussions that follow.

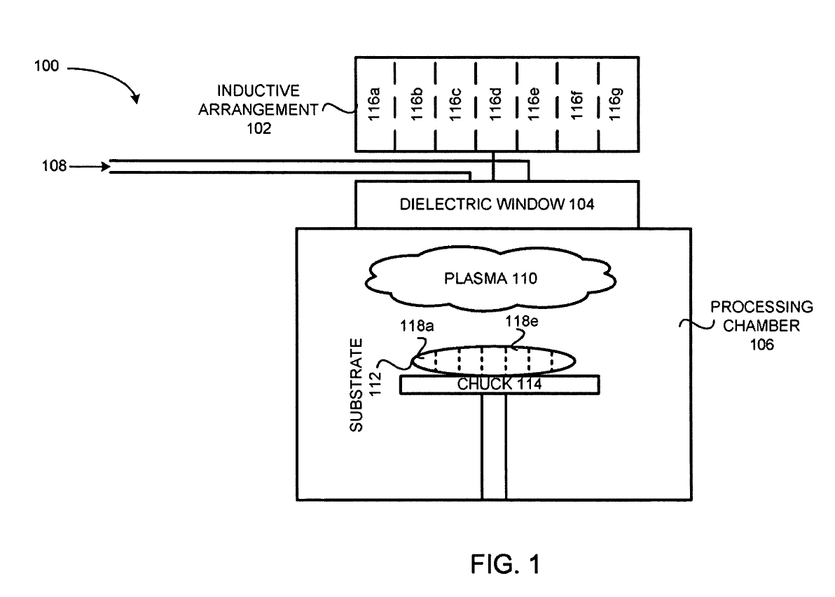

FIG. 1 shows, in an embodiment of the invention, an inductive arrangement for introducing RF energy into a plasma processing system and for performing local control. A plasma environment 100 may include an inductive arrangement 102, which is connected to a dielectric window 104. From inductive arrangement 102, RF energy may flow into a processing chamber 106 to interact with gases that are being fed into processing chamber 106 through a gas distribution arrangement 108. The RF energy may couple with the gas in order to form plasma 110, which is used to etch a substrate 112 that is located on top of an electrostatic chuck 114.

In the prior art, inductive arrangement 102 may be a simple antenna arrangement, a concentric antenna, two spiral antenna intertwined with one another, and the like. Regardless of the arrangement, the inductive arrangement usually has a primarily global effect on the substrate and limited or no local control is provided. Unlike the prior art, embodiments of the invention provide arrangements that support local control, thereby resulting more controlled environment that is capable of producing more uniform processing.

In an embodiment of the invention, the inductive elements may include a plurality of inductive elements (116a, 116b, 116c, 116d, 116e, 116f, and 116g). Each of the inductive elements may be individually controlled. In an example, a section 118a of substrate 112 may have a potential that is less than a section 118e. To increase the potential at section 118a, the RF current flowing through inductive element 116a may be increased in order to provide sufficient power to create substantially the same potential across sections 118a and 181e of substrate 112. By manipulating control for the inductive elements of inductive arrangement 102, a more uniform processing environment may exist across substrate 112.

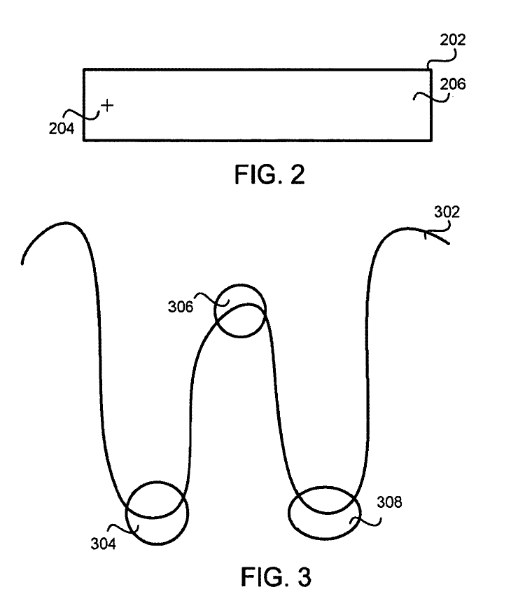

As aforementioned, the inductive elements may be of different shapes. FIG. 2-4 show, in embodiments of the invention, examples of different shapes for an inductive element.

FIG. 2 shows, in an embodiment of the invention, a simple strap 202. Strap 202 may have a positive terminal 204 and a negative terminal 206.

FIG. 3 shows, in an embodiment of the invention, a serpentine shape 302. Serpentine shape 302 may be a virtual link array of counter-rotating inductive elements with multiple bends (bends 304, 306, and 308). These bends constitute virtual current loops. Each of the bends may have a current path flowing in opposite directions. In an example, bend 304 may have current flowing in a clockwise direction, bend 306 may have current flowing in a counter-clockwise direction, and bend 308 may have current flowing in a clockwise direction. The current flow for serpentine shape 302 is the sum of the different current flows.

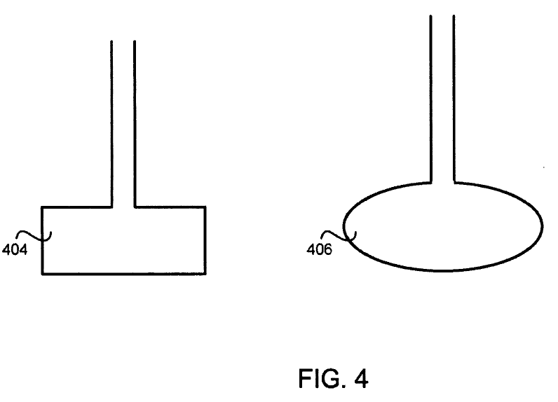

FIG. 4 shows, in an embodiment of the invention, examples of inductive elements with a loop shape. In an embodiment, an inductive element may have a square end (loop 404). In another embodiment, an inductive element may have a round end (loop 406).

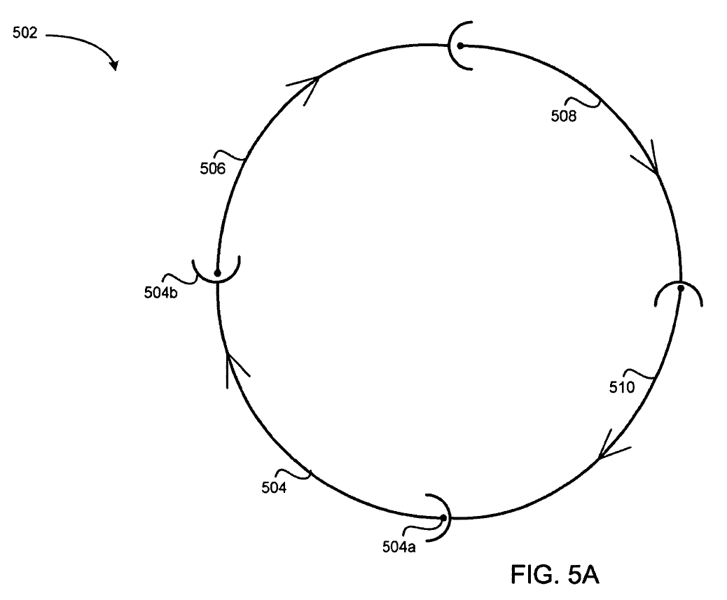

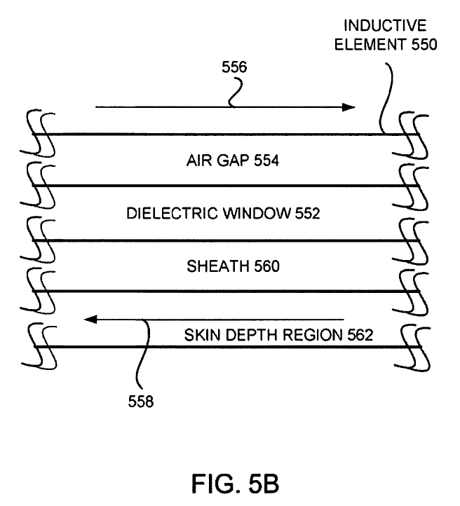

FIGS. 5-10 show, in embodiments of the invention, examples of how the inductive elements may be arranged to provide uniform processing.

FIG. 5A shows, in an embodiment of the invention, an example of a segmented loop arrangement 502. Segmented loop arrangement 502 may include an array of inductive elements (504, 506, 508, and 510). The inductive elements may be of different shapes. In this example, segmented loop arrangement 502 may include an array of inductive elements with a strap shape.

Each inductive element may include two terminals. In an example, inductive element 504 may include a positive terminal 504a and a negative terminal 504b. Terminal 504a may be connected to the center while terminal 504b may be connected to the outside of the coaxial cable. Thus, current flows from terminal 504a to terminal 504b. Underneath, the induced plasma mirror current tends to flow in the opposite direction. To minimize capacitive coupling, the inductive elements have been connected to one another in parallel. Since the inductive elements are connected together and carry current in the same sense, the net effect is a clockwise current flow around segmented loop arrangement 502.

FIG. 5B shows, in an embodiment, a vertical section below a horizontal current flow antenna. An inductive element 550 is placed on top of a dielectric window 552. In an embodiment, an air gap 554 exists between inductive element 550 and dielectric window 552.

A current 556 is flowing on top of inductive element 550 and a reverse mirror current 558 is flowing in the plasma beneath dielectric window 552. Reverse mirror current 558 is a horizontal current flow locally under the inductive antenna but may flow in other directions in the plasma to complete the circuit path as needed. To prevent two adjacent currents associated with two inductive elements from interacting and positively effectively canceling one another at the plasma the adjacent antenna is equal to or greater than the thickness of dielectric window 552, plus the thickness of a sheath 560 and a skin depth region 562. In an embodiment, reverse mirror current 558 is flowing in skin depth region 562. The effective thickness of dielectric window 552 for inductive coupling is the physical thickness. For capacitive coupling, the effective thickness is reduced by the dielectric constant. For this reason, an additional air gap is often introduced between the inductive elements and the dielectric window.

Referring back to FIG. 5A, better uniformity control may be achieved by reducing the voltage for each inductive element if a purely inductive coupling is desired. The reduction in the voltage may minimize capacitive coupling and may enable more radial control. However, since the inductive elements are powered in parallel but physically arranged in series, the same current loop may be achieved as though it was a single current powered from four times the voltage but without the same non-uniformity of capacitive coupling. In particular, there is no dipolar or quadripole moment.

Rather than parallel connections, each segment is individually powered. Adjustments of phases and currents may be performed to introduce a degree of non-uniformity power distribution, thereby achieving the aforementioned compensation for other sources of non-uniformity.

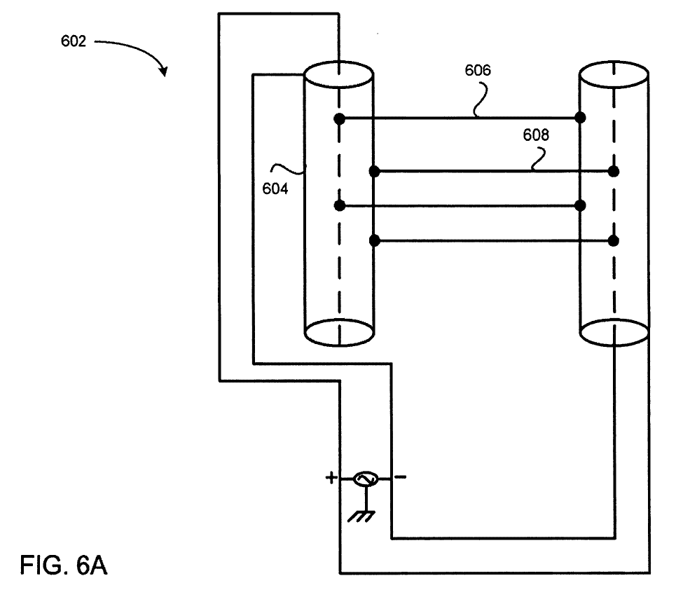

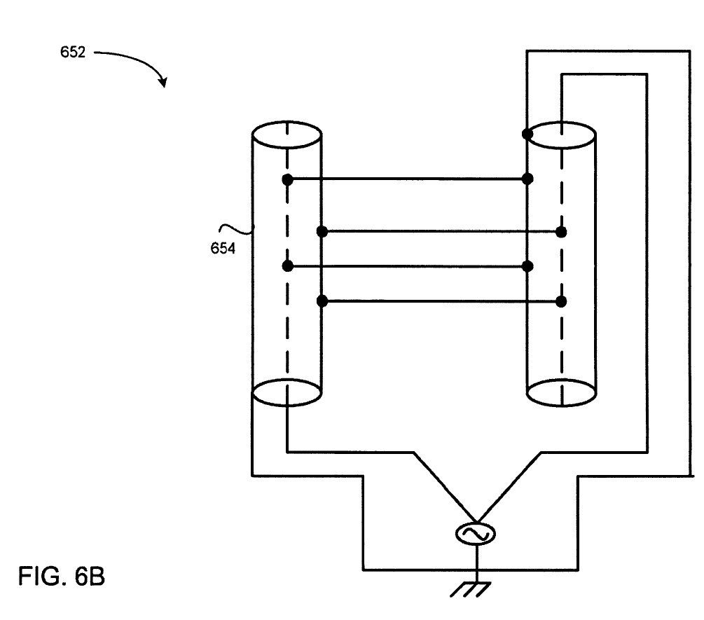

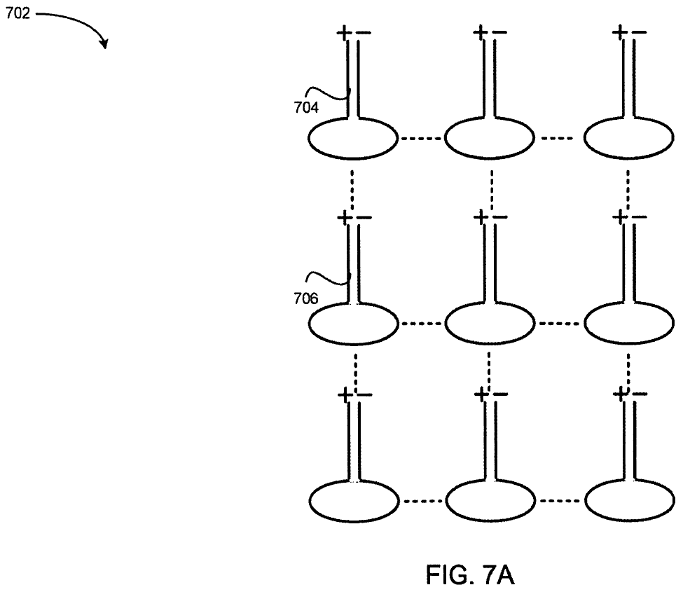

FIGS. 6A and 6B show, in an embodiment, examples of a ladder network arrangement with a feeder bus (e.g., coaxial line). FIG. 6A shows a balanced ladder network arrangement 602 with a feeder bus 604 and FIG. 6B shows an unbalanced ladder network arrangement 652 with a feeder bus 654. Both ladder network arrangements (602 and 652) are examples of Cartesian arrangements in which inductive elements may be arranged in parallel. Each pair of inductive elements may act as a pair of inductive elements in opposition. In an example, a rung 606 and a rung 608 may be a parallel pair of inductive elements with current flowing in opposite directions in order to form a push-pull effect. Each rung may be separated by a distance equal to or greater than the thickness of the dielectric window, the sheath, and the skin depth region. This separation allows the plasma to perceive the current and to enable more localized control. In an embodiment of the invention, the transmission line effect may be considered in calculating the distance between the rungs (e.g., inductive elements) if the RF frequency is high enough such that the structure is a significant portion of the wavelength (e.g., about one quarter of the wavelength). In similar consideration of high frequency operation, the feed structure (e.g., coaxial line) may be made of equal length so that all rungs are uniformly powered. Although unbalanced powering of a ladder network (such as ladder network arrangement 650 shown in FIG. 6B) is possible, this may lead to larger capacitive coupling and non-uniformity. When this is not desired, balanced push-pull operation is preferred. Both the balanced and unbalanced powering cases are shown in FIGS. 6A and 6B, respectively.

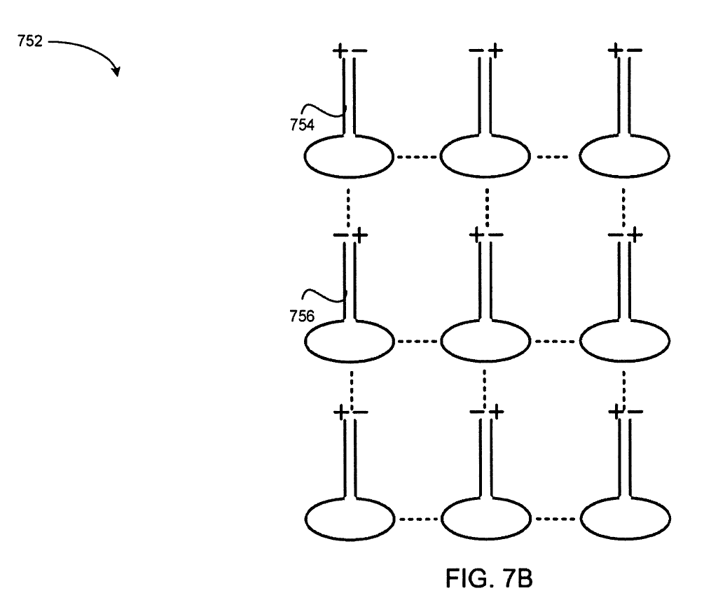

FIG. 7A shows, in an embodiment of the invention, a loop array arrangement 702. Loop array arrangement 702 may include a plurality of inductive elements. In this example, the inductive element is a rounded loop. In an embodiment, if the current flow of each of the inductive elements flows in the same direction, then a global horizontal rotating current may exist. In an example, the current flow of an inductive element 704 flows in the same direction as the current flow for an inductive element 706. In an embodiment, to reduce the global horizontal current flow and to increase local control, the inductive elements may be placed further apart. The distance between the adjacent inductive elements may, be equal to or greater than the thickness of the dielectric window plus the sheath thickness and the skin depth region thickness.

FIG. 7B shows, in an embodiment of the invention, a loop arrangement 752 with current flows flowing in opposite directions. In other words, the current flow for each of the adjacent inductive elements is flowing in opposition to create a push-pull effect. In an example, the current flow of an inductive element 754 and an inductive element 756 are flowing in opposite directions. Since the inductive elements may interfere with one another, a larger distance may exist between adjacent inductive elements to minimize the interference. The distance between the adjacent inductive elements may be equal to or greater than the thickness of the dielectric window plus the sheath thickness and the skin depth thickness.

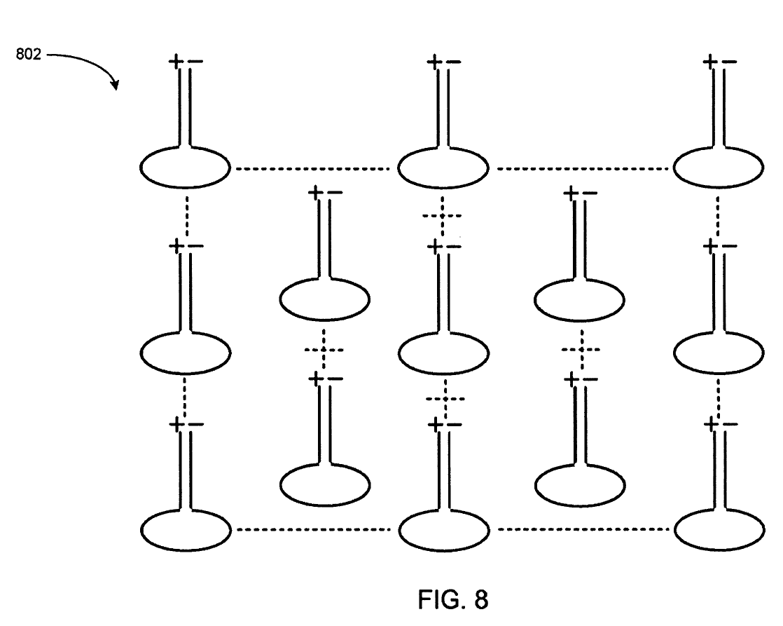

FIG. 8 shows, in an embodiment of the invention, a face-centered arrangement 802. Face-centered arrangement 802 is a Cartesian arrangement with an offset center in the middle. Similar to FIGS. 7A and 7B, each inductive element may be arranged with the current flowing in the same direction and/or the currents flowing in the opposite directions. By having the current flowing in the same direction, the inductive element may be placed closer together. However, the proximity of the inductive elements to one another may reduce the localized control and cause the current flow to have a more global effect. Thus, to enable more localized control, the inductive elements may be placed in a manner that enables currents to flow in the same direction but the inductive element may be placed further apart. In an embodiment, the distance between adjacent inductive elements may be equal to or greater than the thickness of the dielectric window plus the sheath thickness and the skin depth thickness. Similar localized control may be achieved by having the inductive elements arranged in a manner that results in the currents flowing in opposite directions. Thus, localized control may be achieved by spacing the adjacent inductive elements and/or placing the inductive elements into a push-pull arrangement.

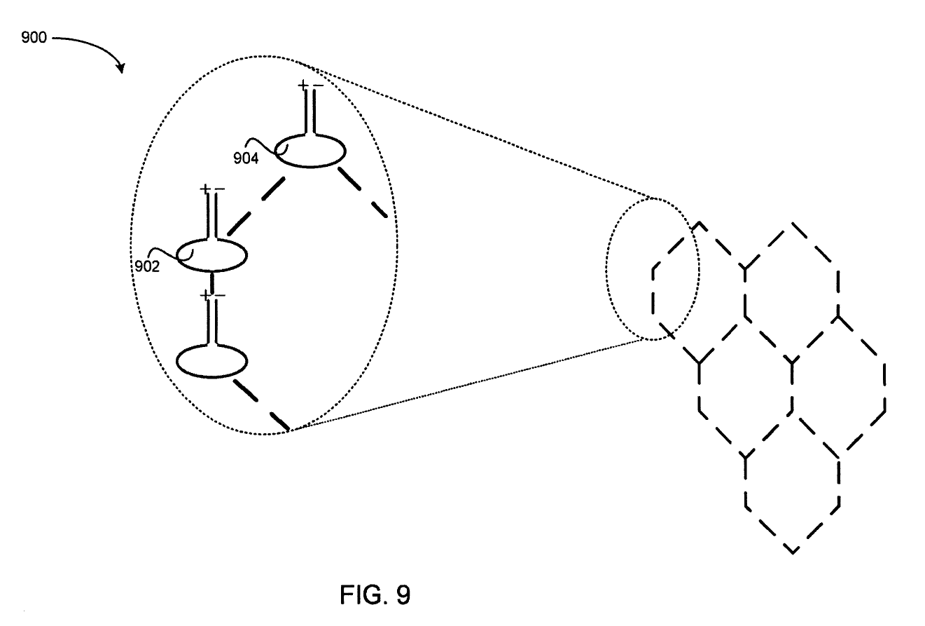

FIG. 9 shows, in an embodiment of the invention, a hexagonal closed pack ring arrangement 900. This particular arrangement is different from a Cartesian arrangement since the space provided for arranging the inductive elements is a circular space. Similar to the other arrangements, the proximity of the inductive elements to one another may affect localized control. As a result, adjacent inductive elements (such as 902 and 904) may be spaced apart by a distance equal to or greater than the thickness of the dielectric window plus the sheath thickness and the skin depth thickness, in an embodiment. The coils are wound and powered in the same sense. Unlike the Cartesian case, where an alternating reversal scheme can be employed in adjacent loops (FIG. 7B), such a scheme can not be performed with a hexagonal array unless a three-phase power scheme is employed.

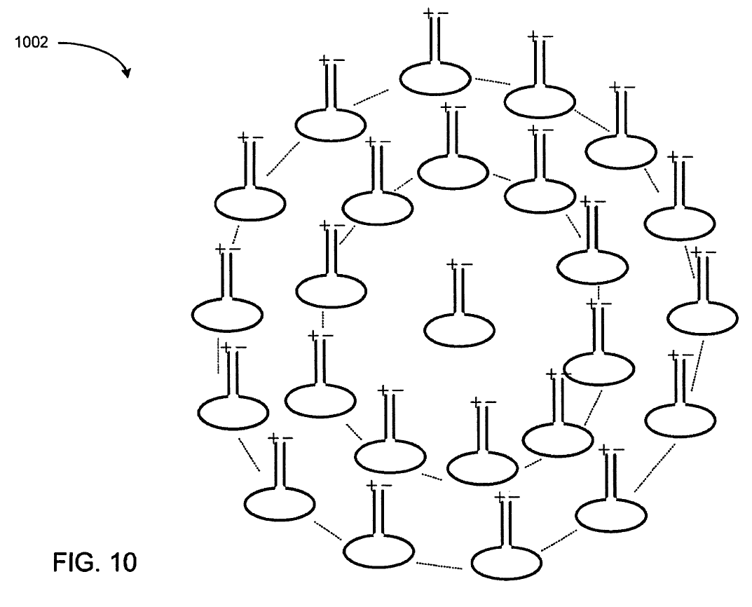

FIG. 10 shows, in an embodiment of the invention, a concentric ring arrangement 1002. This particular arrangement may include a center and a series of concentric rings. Similar to the other arrangements, the proximity of the inductive elements to one another may affect localized control. As a result, adjacent inductive elements may be spaced apart by equal to or greater than the thickness of the dielectric window plus the sheath thickness and the skin depth thickness, in an embodiment. In an embodiment, the number of inductive elements in a given ring may be determined by the granularity of localized control desired. In this case, it is possible to power some or all of the rings alternatively. In other words, all elements in one ring will be powered in the same sense and all elements in another ring will be powered in the same sense but in the opposite direction.

In cases in which currents are powered in the same sense, thereby generating a global current loop, the distance from adjacent loops may be relaxed as the fields are additive and will not cancel each other. In cases in which adjacent elements are powered in the alternating sense, fields of adjacent elements tend to cancel each other at the plasma unless the spacing is sufficient, e.g., equal to or greater than the thickness of the dielectric window plus the sheath thickness and the skin depth thickness, in an embodiment.

As can be appreciated from the foregoing, embodiments of the invention enable more effective uniformity control during substrate processing since local control of sections of substrate is provided. As discussed, by providing local control, non-uniform processing result may be substantially reduced. The embodiments of the invention also achieve local control without requiring high RF frequency. Further, the granularity of local control may be realized by the number of inductive elements and/or the distance between each inductive element. Thus, uniformity control during substrate processing may be achieved without having to employ expensive components.

While this invention has been described in terms of several preferred embodiments, there are alterations, permutations, and equivalents, which fall within the scope of this invention. Loops can be square or other closed shape. Loops do not have to be circular. Although various examples are provided herein, it is intended that these examples be illustrative and not limiting with respect to the invention.

Also, the title and summary are provided herein for convenience and should not be used to construe the scope of the claims herein. Further, the abstract is written in a highly abbreviated form and is provided herein for convenience and thus should not be employed to construe or limit the overall invention, which is expressed in the claims. If the term “set” is employed herein, such term is intended to have its commonly understood mathematical meaning to cover zero one, or more than one member. It should also be noted that there are many alternative ways of implementing the methods and apparatuses of the present invention. It is therefore intended that the following appended claims be interpreted as including all such alterations, permutations, and equivalents as fall within the true spirit and scope of the present invention.

What is claimed is:

1. An arrangement for enabling local control of power deliver within a plasma processing system having a plasma processing chamber during processing of a substrate, comprising:
a dielectric window; and
an inductive arrangement, said inductive arrangement being disposed above said dielectric window to enable power to couple with a plasma in said plasma processing system, wherein said inductive arrangement includes a set of inductive elements, said set of inductive elements providing said local control of power delivery to create a substantially uniform plasma in said plasma processing chamber.

2. The arrangement of claim 1 wherein an inductive element of said set of inductive elements being one of a plurality of geometric shapes to facilitate current flow, wherein said plurality of geometric shapes including
a strap shape, wherein an inductive element with said strap shape has a positive terminal and a negative terminal,
a serpentine shape, wherein said serpentine shape includes a link array of counter-rotating inductive elements with multiple bends, wherein currents of adjacent bends of said multiple bends flow in opposite directions, and
a loop shape, wherein said loop shape includes one of a square loop and a round loop.

3. The arrangement of claim 2 wherein said set of inductive elements is arranged in one of a plurality of configurations to substantially minimize coupling between inductive elements of said set of inductive elements and to support said local control of power delivery, said plurality of configurations including
a segmented loop arrangement,
a ladder network arrangement,
a loop array arrangement,
a face-centered arrangement,
a hexagonal closed pack ring arrangement, and
a concentric ring arrangement.

4. The arrangement of claim 3 wherein each inductive element of said segmented loop arrangement includes a pair of terminals, wherein a first terminal of said pair of terminals is connected to a center and a second terminal of said pair of terminals is connected to a coaxial cable to create current flow from said second terminal to said first terminal.

5. The arrangement of claim 4 wherein adjacent inductive elements of said segmented loop arrangement are coupled together to create a horizontal current flow across said segmented loop arrangement.

6. The arrangement of claim 3 wherein a pair of inductive elements of said ladder network arrangement is arranged in parallel, wherein said pair of inductive elements creates a push-pull effect in which current from a first inductive element of said pair of inductive elements flows in opposition to current from a second inductive element of said pair of inductive elements.

7. The arrangement of claim 6 wherein a first pair of inductive elements of said set of inductive elements is separated from a second pair of inductive elements of said set of inductive elements by at least said dielectric window thickness, a sheath thickness, and a skin depth thickness.

8. The arrangement of claim 7 wherein said ladder network arrangement is configured to include a coaxial line.

9. The arrangement of claim 3 wherein said set of inductive elements of a loop array arrangement is arranged as a loop.

10. The arrangement of claim 9 wherein said adjacent inductive elements of said set of inductive elements is arranged to generate a current flowing in the same direction to create a global horizontal rotating current.

11. The arrangement of claim 9 wherein current for each adjacent inductive element of said loop array arrangement flows in opposite directions to create a push-pull current flow.

12. The arrangement of claim 9 wherein each inductive element of said loop array arrangement separated from another inductive element of said loop array arrangement by at least a distance of said dielectric window thickness, a sheath thickness, and a skin depth thickness to minimize coupling between adjacent inductive elements and to enable said local control of power delivery.

13. The arrangement of claim 3 wherein said set of inductive elements with said face-centered arrangement being arranged in a Cartesian arrangement with an offset center.

14. The arrangement of claim 13 wherein current for each adjacent inductive element of said face-centered arrangement flows in the same direction to create a global horizontal rotating current.

15. The arrangement of claim 13 wherein current for each inductive element of said face-centered arrangement flows in opposite direction relative to current in an adjacent inductive element of said face-centered arrangement to create a push-pull current flow.

16. The arrangement of claim 13 wherein each inductive element within said face-centered arrangement is separated from another inductive element of said face-centered arrangement by at least a distance of said dielectric window thickness, a sheath thickness, and a skin depth thickness to minimize coupling between adjacent inductive elements and to enable said local control of power delivery.

17. The arrangement of claim 1 wherein said set of inductive elements with said hexagonal closed pack ring arrangement is arranged within a circular spatial arrangement.

18. The arrangement of claim 17 wherein each inductive element of said set of inductive elements is separated from another inductive element of said hexagonal closed pack ring arrangement by at least a distance of said dielectric window thickness, a sheath thickness, and a skin depth thickness to minimize coupling between adjacent inductive elements and to enable said local control of power delivery.

19. The arrangement of claim 1 wherein said set of inductive elements being a concentric ring arrangement, wherein said concentric ring arrangement includes a center and a series of concentric rings.

20. The arrangement of claim 19 wherein each inductive element of said set of inductive elements is separated from another inductive element of said concentric ring arrangement by at least a distance of said dielectric window thickness, a sheath thickness, and a skin depth thickness to minimize coupling between adjacent inductive elements and to enable said local control of power delivery.
